(19) United States
(12) Patent Application Publication
(10) Pub. No.: US 2019/0252417 A1
(43) Pub. Date: Aug. 15, 2019

(54) PREPARATION METHOD FOR ARRAY SUBSTRATE, ARRAY SUBSTRATE AND DISPLAY DEVICE

(71) Applicants: HEFEI BOE OPTOELECTRONICS TECHNOLOGY CO., LTD., Anhui (CN); BOE TECHNOLOGY GROUP CO., LTD., Beijing (CN)

(72) Inventor: Dezhi XU, Beijing (CN)

(21) Appl. No.: 16/333,322

(22) PCT Filed: May 9, 2018
(86) PCT No.: PCT/CN2018/086106

§ 371 Date: Mar. 14, 2019

(30) Foreign Application Priority Data
May 17, 2017 (CN) 201710349635.6

(51) Int. Cl. H01L 27/12; H01L 27/32

(52) U.S. Cl. CPC H01L 27/1244; H01L 27/1288; H01L 27/3276; H01L 27/1262

(57) ABSTRACT

The present disclosure provides a preparation method for an array substrate, an array substrate, and a display device. The preparation method for an array substrate comprises: forming an insulating material layer on a substrate; forming a first conductive material layer on the insulating material layer, and performing a patterning process on the first conductive material layer to form a plurality of signal lines arranged in an array.

### RELATED APPLICATION

The present application is the U.S. national phase entry of PCT/CN2018/086106, with an international filing date of May 9, 2018, which claims the benefit of Chinese Patent Application No. 201710349635.6, filed on May 17, 2017, the entire disclosure of which is incorporated herein by reference.

### FIELD

The present disclosure relates to the field of display. Specifically, the present disclosure relates to a preparation method for an array substrate, an array substrate and a display device.

### BACKGROUND

With the continuous advancement of technology, a liquid crystal display (LCD) has been applied to many aspects of the modern user life such as a TV screen, a computer screen, a mobile phone screen, etc., owing to its advantages such as thinness, no radiation, low power consumption, and the like, which brings convenience to the user's life.

A thin film transistor liquid crystal display (TFT-LCD) is a commonly used liquid crystal display, which mainly relies on power supply of a thin film transistor (TFT) for adjusting the deflection direction of liquid crystal molecules, and enables a liquid crystal display screen to display different images by means of a color filter, etc. Signal lines, such as gate lines, composed of metal wires are distributed on an array substrate of the thin film transistor liquid crystal display. Generally, in order to solve the resistance/capacitance delay effect caused by a resistance in the thin film transistor, a metal wire having low resistivity and high electromigration resistance, for example, a copper wire or the like, is employed.

### SUMMARY

An exemplary embodiment provides a preparation method for an array substrate, comprising:

forming an insulating material layer on a substrate;

forming a first conductive material layer on the insulating material layer; and

performing a patterning process on the first conductive material layer to form a plurality of signal lines arranged in an array.

According to some exemplary embodiments, after forming an insulating material layer on the substrate, the method further comprises:

performing a patterning process on the insulating material layer to form a groove on a side of the insulating material layer away from the substrate.

According to some exemplary embodiments, said forming a first conductive material layer on the insulating material layer and performing a patterning process on the first conductive material layer to form a plurality of signal lines arranged in an array include:

forming a first conductive material layer on a patterned insulating material layer, so that the first conductive material layer covers and fills the groove;

performing a patterning process on the first conductive material layer to remove the first conductive material layer covering regions on a side of the insulating material layer away from the substrate other than the groove, so that the first conductive material layer filling the groove forms the signal line.

According to some exemplary embodiments, a depth of the groove is not greater than a thickness of the insulating material layer.

According to some exemplary embodiments, said performing a patterning process on the insulating material layer includes:

coating a photoresist on the insulating material layer, and performing pre-drying treatment on the photoresist;

after the pre-drying treatment, performing an exposure process on the photoresist by means of a mask;

after the exposure process, performing a development process on the photoresist to pattern the photoresist, and curing a patterned photoresist by post-drying treatment; and

performing an etching process on the insulating material layer using the patterned photoresist as a mask to form a groove on a side of the insulating material layer away from the substrate.

According to some exemplary embodiments, the photoresist has a coating thickness ranging from about 1.1 to 3.1 μm.

According to some exemplary embodiments, the pre-drying treatment has a drying temperature ranging from about 100 to 110 degrees Celsius and drying time of about 50 to 70 seconds.

According to some exemplary embodiments, the photoresist after the pre-drying treatment has a thickness ranging from about 1.0 to 3.0 μm.

According to some exemplary embodiments, the post-drying treatment has a drying temperature ranging from about 100 to 140 degrees Celsius and drying time of about 50 to 70 seconds.

According to some exemplary embodiments, after performing a patterning process on the first conductive material layer, the method further comprises:

forming an insulating layer on the signal line and the insulating material layer;

forming an active layer on the insulating layer, and performing a patterning process on the active layer; and

forming a second conductive material layer on an patterned active layer and the insulating layer, and performing a patterning process on the second conductive material layer to form a source and a drain.

According to some exemplary embodiments, a material of the insulating material layer includes one or more of silicon nitride, silicon oxide, titanium oxide and aluminum oxide, and the first conductive material layer includes copper.

According to some exemplary embodiments, the thickness of the insulating material layer ranges from about 100 to 400 nanometers.

Another exemplary embodiment provides an array substrate comprising a substrate, an insulating material layer, and a signal line, wherein the insulating material layer is on the substrate, and the signal line is on a side of the insulating material layer away from the substrate.

According to some exemplary embodiments, a groove is disposed on a side of the insulating material layer away from the substrate, and the signal line is embedded in the groove.

According to some exemplary embodiments, the above array substrate further comprises an insulating layer, an active layer, a source and a drain. The insulating layer is on the signal line and the insulating material layer, the active layer is on a side of the insulating layer away from the signal line, and the source and the drain are on sides of the insulating layer and the active layer away from one of the signal line and the insulating material layer.

A further exemplary embodiment provides a display device comprising any of the array substrates described above. Additional aspects and advantages of the present invention will be partially set forth in the description below, which will become apparent from the description below, or be realized by practicing the present disclosure.

### BRIEF DESCRIPTION OF THE DRAWINGS

The above and/or additional aspects and advantages of the present disclosure will become apparent and comprehensible from the description of embodiments below with reference to the accompanying drawings, wherein

FIG. 1 is a flow chart of a preparation method for an array substrate provided by embodiments of the present disclosure;

FIG. 2 is a flow chart of a preparation method for an array substrate provided by an embodiment of the present disclosure;

FIG. 3 is a schematic view illustrating a process of forming an insulating material layer and a first conductive material layer on a substrate in the preparation method shown in FIG. 2;

FIG. 4 is a schematic view illustrating a process of coating a photoresist on the first conductive material layer in the preparation method shown in FIG. 2;

FIG. 5 is a schematic view illustrating a process of performing an exposure process on the photoresist in the preparation method shown in FIG. 2;

FIG. 6 is a schematic view illustrating a process of performing an etching process on the first conductive material layer using a patterned photoresist in the preparation method shown in FIG. 2;

FIG. 7 is a schematic view of an array substrate after an etching process has been performed on the first conductive material layer in the preparation method shown in FIG. 2;

FIG. 8 is a flow chart of a preparation method for an array substrate provided by another embodiment of the present disclosure;

FIG. 9 is a flow chart of performing a patterning process on an insulating material layer in the preparation method shown in FIG. 8;

FIG. 10 is a schematic view illustrating a process of performing an exposure process on a photoresist in the preparation method shown in FIG. 8;

FIG. 11 is a schematic view illustrating a process of performing an etching process on the insulating material layer using a patterned photoresist in the preparation method shown in FIG. 8;

FIG. 12 is a schematic view of an array substrate after an etching process has been performed on the insulating material layer in the preparation method shown in FIG. 8;

FIG. 13 is a schematic view illustrating a process of forming a first conductive material layer on a patterned insulating material layer in the preparation method shown in FIG. 8;

FIG. 14 is a schematic view illustrating a process of performing an etching process on the first conductive material layer using a patterned photoresist in the preparation method shown in FIG. 8;

FIG. 15 is a schematic view of an array substrate after an etching process has been performed on the first conductive material layer in the preparation method shown in FIG. 8;

FIG. 16 is a schematic view illustrating a process of performing an etching process on the first conductive material layer using a patterned photoresist in the preparation method shown in FIG. 8;

FIG. 17 is a schematic structural view of an array substrate provided by a further embodiment of the present disclosure; and

FIG. 18 is a schematic structural view of an array substrate provided by yet another embodiment of the present disclosure.

### DETAILED DESCRIPTION

Exemplary embodiments of the present disclosure are described in detail below, and examples of the embodiments are illustrated in the accompanying drawings, in which the same or similar reference numerals are used to denote the same or similar elements or elements having the same or similar functions. The embodiments described below with reference to the accompanying drawings are exemplary, which are only used for illustrating the present disclosure and cannot be construed as limiting the present disclosure.

It can be understood by those skilled in the art that singular forms “a”, “an”, “the” and “said” used herein may also include plural forms unless stated otherwise. It is to be further understood that the wording “comprise” used in the specification of the present disclosure indicates existence of said feature, integer, step, operations, element and/or component, but does not exclude existence or addition of one or more of other features, integers, steps, operations, elements, components and/or groups thereof. It is to be understood that when an element is referred to as being “connected” or “coupled” to another element, it can be directly connected or coupled to the other element, or an intermediate element may be present. Further, “connected” or “coupled” as used herein may include either a wireless connection or a wireless coupling. The wording “and/or” used herein includes all or any one and all combinations of one or more of associated items listed.

Those skilled in the art will appreciate that all the terms (including technical and scientific terms) used herein have the same meanings as commonly understood by those ordinarily skilled in the art to which the present disclosure pertains, unless otherwise defined. It is to be further understood that terms such as those defined in a general dictionary should be understood to have meanings consistent with the meanings in the context of the prior art, and will not be explained by idealized or excessively formal meanings unless specifically defined.

Typically, in preparing copper wires (e.g., gate lines) in an array substrate, copper easily reacts with silicon in the substrate at high temperatures to produce products such as copper silicide (CuSi₃), thereby resulting in a very high contact resistance. Moreover, copper has poor adhesion with the substrate and can be easily peeled off from the substrate.

In order to solve the above problem, a barrier metal (for example, molybdenum or titanium or the like) may be deposited between the substrate and a copper wire, combining copper and the barrier metal into a composite metal wire.

A method for preparing a composite metal wire in the array substrate may include: firstly depositing a barrier metal and a copper film on a substrate, and then performing a patterning process on the barrier metal and the copper film using an etching solution to prepare a composite metal wire.

However, the inventors of the present disclosure have found that a same etching solution usually has different etching rates for different metals, and in practical applications, an etching solution mainly for copper is usually selected to perform a patterning process on the composite metal. This easily causes the barrier metal to be incompletely etched, so that the barrier metal remains on substrate. The residual barrier metal easily results in occurrence of an accidental short circuit or other malfunctions in related circuits, which seriously affects the yield of the array substrate. Moreover, the resistance of the barrier metal is generally large, so that the combined surface resistance of the composite metal wire formed by copper and the barrier metal is greater than the surface resistance of a pure copper wire, and thus the advantages of using a copper wire in terms of low resistivity cannot be fully embodied. Therefore, the array substrate prepared by the above method will still have a severe resistance/capacitance delay effect, which decreases the response speeds of related circuits, and in turn decreases the response speed of the entire array substrate.

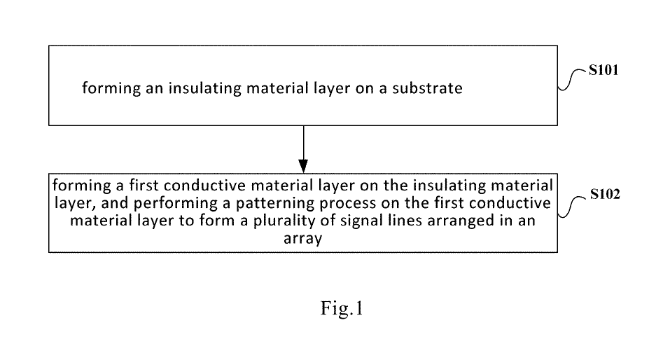

In view of this, an exemplary embodiment provides a preparation method for an array substrate. A flow chart of this method is as shown in FIG. 1, specifically including steps of:

at step S101, forming an insulating material layer on a substrate; and

at step S102, forming a first conductive material layer on the insulating material layer, and performing a patterning process on the first conductive material layer to form a plurality of signal lines arranged in an array.

In particular, the signal lines may specifically include gate lines, data lines, and the like.

In the above-described preparation method for an array substrate, an insulating material layer is formed between the first conductive material layer and the substrate, and the insulating material layer can be used as an interface modifying layer, which can avoid the problem that poor adhesion between the first conductive material layer and the substrate causes the first conductive material layer to be easily peeled off from the substrate.

Further, since the insulating material layer is not electrically conductive, it does not affect the preparation of signal lines, so that it is not necessary to perform a patterning process on the insulating material layer. Therefore, the above-described preparation method for an array substrate can prevent the problem that incomplete etching of the barrier metal results in occurrence of an accidental short circuit or other malfunctions in related circuits.

In addition, in the above-described preparation method for an array substrate, when the signal lines are being prepared, no barrier metal is introduced, while the first conductive material layer is directly used instead of the composite metal wire to participate in conduction, which can thus effectively reduce the resistivity of a wire, improve the transmission speed of an electrical signal, and in turn improves the response speed of the array substrate.

The technical solutions of exemplary embodiments are specifically described below with reference to the accompanying drawings.

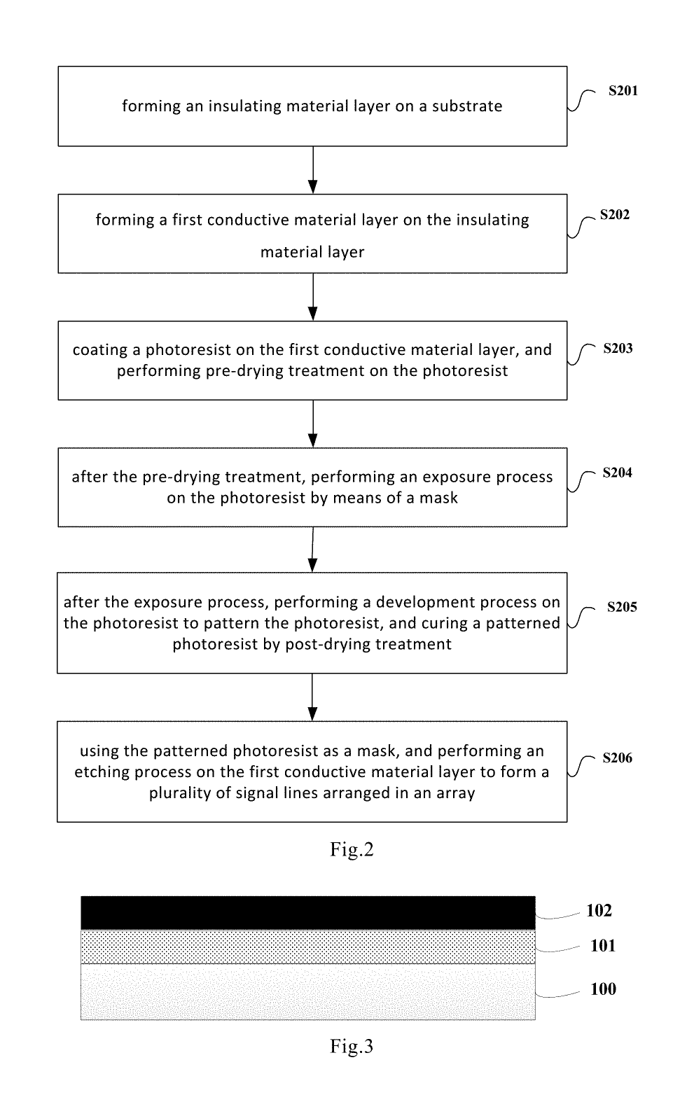

FIG. 2 is a flow chart of a preparation method for an array substrate provided by an embodiment of the present disclosure. As shown in FIG. 2, at S201, an insulating material layer is formed on the substrate.

In this step, the insulating material layer may be formed on the substrate by various methods, including a physical coating method and a chemical coating method, wherein the physical coating method may be physical vapor deposition, and the chemical coating method may be chemical vapor deposition, or a sol-gel method, and the like.

In an exemplary embodiment, the above insulating material layer is specifically an inorganic non-metal layer, and the material of the inorganic non-metal layer may include at least one of silicon nitride (SiNₓ), silicon oxide (SiO₂), titanium oxide (TiO₂), aluminum oxide (Al₂O₃), and the like. The thickness of the insulating material layer formed on the substrate may range from about 100 to 400 nanometers. Compared to an insulating material layer having a thickness less than 100 nm, an insulating material layer having the above thickness range has better resistance to electrostatic breakdown. Compared to an insulating material layer having a thickness greater than 400 nm, an insulating material having the above thickness range has shorter film formation time upon deposition and accordingly has higher film formation efficiency.

As shown in FIG. 2, at step S202, a first conductive material layer is formed on the insulating material layer.

In this step, the first conductive material layer may be formed on the insulating material layer formed in step S201 by various methods, including a physical coating method such as magnetron sputtering coating, or a chemical coating method such as chemical vapor deposition, and the like.

FIG. 3 is a schematic view illustrating a process of forming an insulating material layer and a first conductive material layer on a substrate in the preparation method shown in FIG. 2. As shown in FIG. 3, an insulating material layer 101 is formed on a substrate 100, and a first conductive material layer 102 is formed on the insulating material layer 101. The material of the first conductive material layer may be aluminum or copper, wherein copper has a resistivity smaller than that of aluminum. Other metal or non-metal conductive materials may also be employed, which are not specifically limited herein.

At step S203, a photoresist is coated on the first conductive material layer, and the photoresist is subjected to pre-drying treatment.

In this step, the photoresist may be coated on the first conductive material layer by a slit coating technique, a spin coating technique or the like, so that it forms a film on the first conductive material layer. As shown in FIG. 4, a photoresist 103 is coated on the first conductive material layer 102.

In an exemplary embodiment, the photoresist may have a coating thickness ranging from about 1.1 to 3.1 μm. Compared to a photoresist having a thickness less than 1.1 μm, a photoresist having the above thickness range can decrease the probability of light penetrating the photoresist and causing damage to other layers during photolithography. Compared to a photoresist having a thickness greater than 3.1 μm, a photoresist having the above thickness range makes the film formed by the photoresist more uniform, thereby improving the film formation efficiency of the photoresist.

After the photoresist is coated, the photoresist that has formed a film is subjected to pre-drying treatment so as to cure the photoresist film.

In an exemplary embodiment, the pre-drying treatment for the photoresist has a drying temperature ranging from about 100 to 110 degrees Celsius and drying time of about 50 to 70 seconds. Compared to a drying temperature of less than 100 degrees Celsius, the above drying temperature range can better cure the photoresist film. Compared to a drying temperature greater than 110 degrees Celsius, the above drying temperature range can decrease the probability of the photoresist remaining on the first conductive material layer after development due to being overly cured. The drying time of about 50 to 70 seconds is used for a similar reason. In particular, the pre-drying time may be specifically about 60 seconds.

In an exemplary embodiment, the photoresist film that has undergone the pre-drying treatment has a thickness ranging from about 1.0 to 3.0 μm. In particular, the photoresist film that has undergone the pre-drying treatment may have a thickness of about 2.2 μm by reasonably controlling the thickness of the coated photoresist film before the pre-drying treatment, and/or the conditions for the pre-drying treatment.

Returning to FIG. 2, at step S204, after the pre-drying treatment, an exposure process is performed on the photoresist by means of a mask.

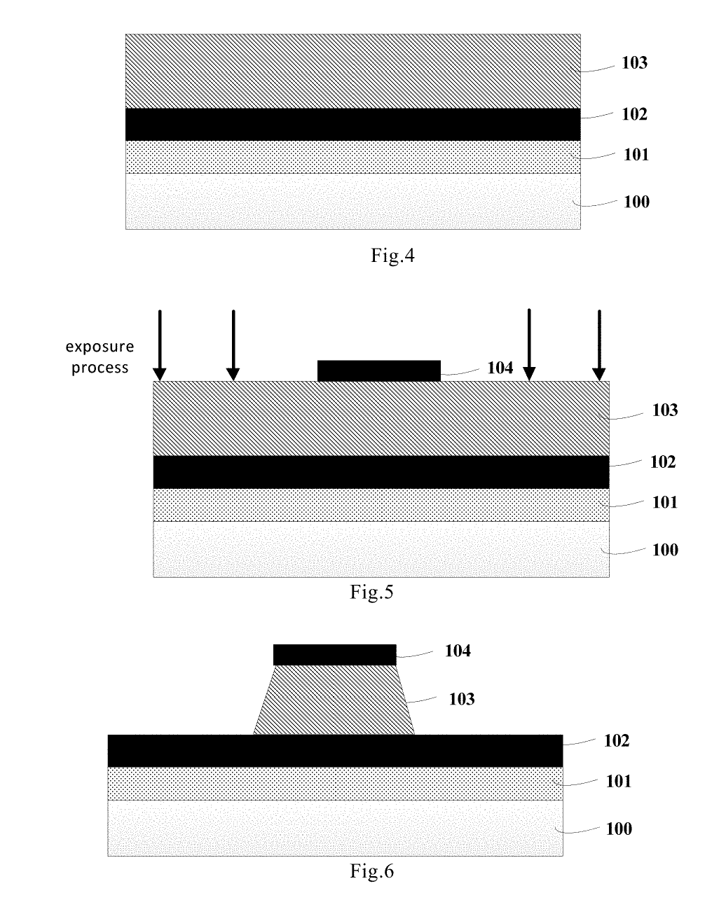

After the pre-drying treatment, an exposure process is performed on the photoresist by means of a mask, as shown in FIG. 5. The photoresist 103 is first covered by a mask 104, and an exposure process is performed on the photoresist 103.

At step S205, after the exposure process, a development process is performed on the photoresist so that the photoresist is patterned, and the patterned photoresist is cured by post-drying treatment.

The photoresist used in exemplary embodiments may be a positive photoresist or a negative photoresist.

When a positive photoresist is used, after the exposure process has been performed on the photoresist, the photoresist (exposed region) not covered by the mask reacts to become soluble in a developer solution, while the photoresist (non-exposed region) covered by the mask is insoluble in the developer solution. Thus, the photoresist after the development process has a pattern substantially the same as or corresponding to the shape of the mask, as shown in FIG. 6, wherein the photoresist 103 is a photoresist after the development process.

When a negative photoresist is used, after the exposure process has been performed on the photoresist, an exposed region becomes insoluble in the developer solution, while a non-exposed region is soluble in the developer solution. Thus, the photoresist after the development process has a pattern opposite to the shape of the mask. The specific etching process and the mask can be adjusted according to the types of the photoresist and the developer solution. No particular limitation is imposed in this regard in embodiments of the present disclosure.

After a patterning process has been performed on the photoresist, the patterned photoresist is subjected to post-drying treatment to cure the patterned photoresist film.

In an exemplary embodiment, the post-drying treatment has a drying temperature ranging from about 100 to 140 degrees Celsius and drying time of about 50 to 70 seconds. Compared to a drying temperature of less than 100 degrees Celsius, the above drying temperature range can better cure the patterned photoresist film. Compared to a drying temperature greater than 140 degrees Celsius, the above drying temperature range can decrease the probability of generating residues when the photoresist is peeled off subsequently because the photoresist is overly cured. The drying time of about 50 to 70 seconds is used for a similar reason. In particular, the drying temperature for the post-drying treatment may be about 120 degrees Celsius, and the drying time may be about 60 seconds.

At step S206, the patterned photoresist is used as a mask, and an etching process is performed on the first conductive material layer to form a plurality of signal lines arranged in an array.

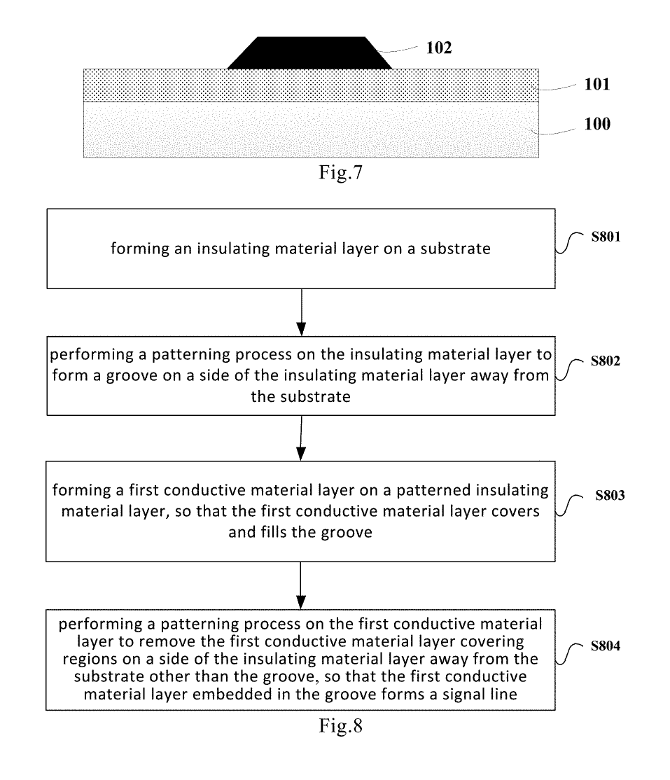

In this step, the patterned photoresist in step S205 may be used as a mask by various methods to etch the first conductive material layer, including wet etching and dry etching. Taking the wet etching as an example, if the material of the first conductive material layer is copper, a region of the first conductive material layer not covered by the mask may be etched using a hydrogen peroxide etching solution. FIG. 7 illustrates the first conductive material layer 102 (signal line) obtained by etching using the photoresist 103 in FIG. 6 as a mask.

In an exemplary embodiment, after a patterning process has been performed on the first conductive material layer to form signal lines, one or more of the following steps may be further included:

forming an insulating layer on the signal lines and the insulating material layer, and forming an active layer on the insulating layer;

performing a patterning process on the active layer;

forming a second conductive material layer on a patterned active layer and the insulating layer;

performing a patterning process on the second conductive material layer to form a source and a drain.

It can be seen from FIG. 3 to FIG. 7 that in the above-described preparation method for an above array substrate provided by an embodiment of the present disclosure, an insulating material layer 101 is formed between the substrate 100 and the first conductive material layer 102, and the insulating material layer 101 can be used as an interface modifying layer, which can solve the problem that poor adhesion between the first conductive material layer 102 and the substrate 100 causes the first conductive material layer 102 to be easily peeled off from the substrate 100.

Further, since the insulating material layer 101 is not electrically conductive, etching is not needed. In practice, when a patterning process is performed on the first conductive material layer 102 using an etching solution, it is difficult for the insulating material layer 101 to be etched by the etching solution. Therefore, embodiments of the present disclosure can prevent the problem that incomplete etching of the barrier metal results in occurrence of an accidental short circuit or other malfunctions in related circuits.

In addition, in exemplary embodiments, when the signal line is being prepared, no barrier metal is introduced, thus the prepared signal line does not contain a barrier metal, so that the metal of the signal line provided by exemplary embodiments is more simplified. In particular, the signal line may include a single metallic material (including reasonable impurities), such as copper. In embodiments of the present disclosure, use of a single-metal (e.g. copper) wire with low resistivity can exhibit the advantages of the wire in terms of low resistance, which thus reduces the delay effect of the signal line in the array substrate, improves the response speeds of related circuits, and in turn increases the response speed of the entire array substrate.

FIG. 8 is a flow chart of a preparation method for an array substrate provided by another embodiment of the present disclosure. As shown in FIG. 8, the preparation method comprises steps of:

at step S801, forming an insulating material layer on a substrate;

at step S802, performing a patterning process on the insulating material layer to form a groove on a side of the insulating material layer away from the substrate;

at step S803, forming a first conductive material layer on a patterned insulating material layer, so that the first conductive material layer covers and fills the groove;

at step S804, performing a patterning process on the first conductive material layer to remove a first conductive material layer covering regions on a side of the insulating material layer away from the substrate other than the groove, and leave the first conductive material layer that fills the groove to serve as a signal line.

In the above-described preparation method for an array substrate, an insulating material layer is formed between the first conductive material layer and the substrate, and the insulating material layer can be used as an interface modifying layer, which can solve the problem that poor adhesion between the first conductive material layer and the substrate causes the first conductive material layer to be easily peeled off from the substrate.

Further, since the insulating material layer is not electrically conductive, it does not affect the preparation of signal lines, so that it is not necessary to perform a patterning process on the insulating material layer. Therefore, the above preparation method for an array substrate can prevent the problem that incomplete etching of the barrier metal results in occurrence of an accidental short circuit or other malfunctions in related circuits.

In addition, in the above preparation method for an array substrate, when the signal line is being prepared, no barrier metal is introduced, while the first conductive material layer is directly used instead of the composite metal wire to participate in conduction, which can thus effectively decrease the resistivity of a wire, improve the transmission speed of an electrical signal, and in turn increase the response speed of the array substrate.

Further, by forming a groove on a side of the patterned insulating material layer away from the substrate, and embedding the patterned first conductive material layer (signal line) in the groove, a level difference between a plurality of film layers above the signal line resulting from the signal line can be greatly reduced, which in turn decreases the probability of breakage of the signal line caused by the level difference between film layers.

Implementations of the steps of the above preparation method for an array substrate will be further described below.

In the above step S801, the method for forming an insulating material layer on the substrate may be identical to the method for forming an insulating material layer on the substrate as described in step S201, and details are not described here again.

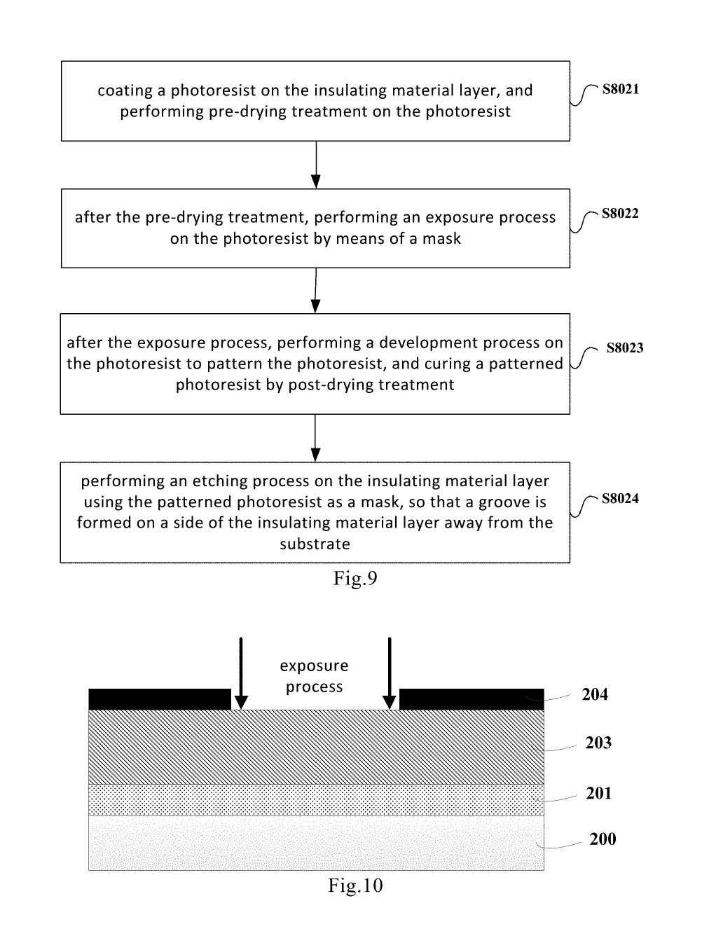

In an exemplary embodiment, in the above step S802, a specific method for performing a patterning process on the insulating material layer to form a groove on a side of the insulating material layer away from the substrate may be as shown in FIG. 9.

Specifically, at step S8021, a photoresist is coated on the insulating material layer, and the photoresist is subjected to pre-drying treatment.

In this step, the photoresist may be coated on the insulating material layer by a slit coating technique, a spin coating technique or the like so that the photoresist forms a film on the insulating material layer.

In an exemplary embodiment, the photoresist may have a coating thickness ranging from about 1.1 to 3.1 μm. Compared to a photoresist having a thickness less than 1.1 μm, a photoresist having the above thickness range can decrease the probability of light penetrating the photoresist and causing damage to other layers during photolithography. Compared to a photoresist having a thickness greater than 3.1 μm, a photoresist having the above thickness range makes the film formed by the photoresist more uniform, thereby improving the film formation efficiency of the photoresist.

After the photoresist is coated, the photoresist that has formed a film is subjected to pre-drying treatment to cure the photoresist film.

In an exemplary embodiment, the pre-drying treatment for the photoresist has a drying temperature ranging from about 100 to 110 degrees Celsius and drying time of 50 to 70 seconds. Compared to a drying temperature of less than 100 degrees Celsius, the above drying temperature range can better cure the photoresist film. Compared to a drying temperature greater than 110 degrees Celsius, the above drying temperature range can decrease the probability of the photoresist remaining on the insulating material layer after development due to being overly cured. The drying time of 50 to 70 seconds is used for a similar reason. In particular, the pre-drying time may be specifically about 60 seconds.

In an exemplary embodiment, the photoresist film that has undergone pre-drying treatment has a thickness ranging from about 1.0 to 3.0 μm. In particular, the photoresist film that has undergone pre-drying treatment may have a thickness of about 2.2 μm by reasonably controlling the thickness of the photoresist film coated before the pre-drying treatment, and/or the conditions for the pre-drying treatment.

Returning to FIG. 9, at step S8022, after the pre-drying treatment, an exposure process is performed on the photoresist by means of a mask.

After the pre-drying treatment, an exposure treatment is performed on the photoresist by means of a mask, as specifically shown in FIG. 10. A photoresist 203 is first covered by a mask 204, and then an exposure process is performed on the photoresist 203.

It can be understood that when the photoresist is a positive photoresist, the position and shape of a light-transmitting region in the mask 204 substantially coincide with the position and shape of a groove to be formed subsequently.

At step S8023, after the exposure process, a development process is performed on the photoresist so that the photoresist is patterned, and the patterned photoresist is cured by post-drying treatment.

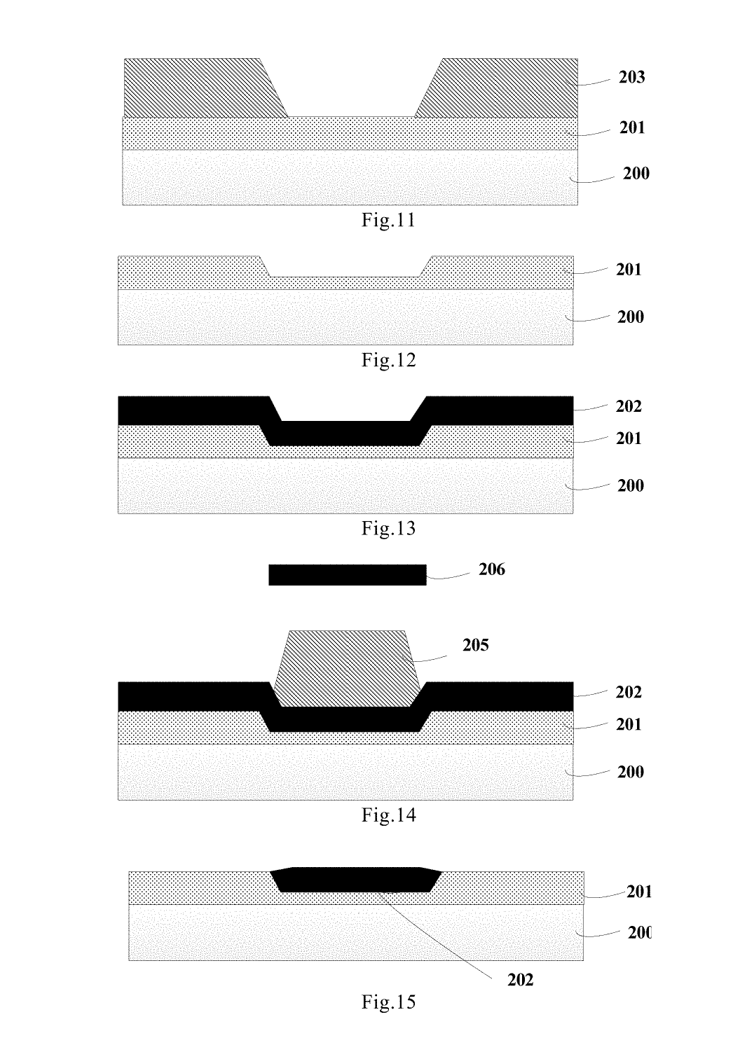

The photoresist used in exemplary embodiments may be a positive photoresist or a negative photoresist. Taking the positive photoresist as an example, a pattern obtained after performing a development process on the photoresist 203 using the mask 204 in FIG. 10 is as shown in FIG. 11.

As used herein, a patterned photoresist means that in the case of a positive photoresist, partial regions on a side of the insulating material layer away from the substrate are covered by the photoresist while the photoresist in other regions has been removed during development. At that time, the position and the shape of a region on a side of the insulating material layer away from the substrate which is not covered by the photoresist substantially coincide with the position and the shape of a groove to be formed subsequently.

After performing a patterning process on the photoresist, the patterned photoresist is subjected to post-drying treatment to cure the patterned photoresist film.

In an exemplary embodiment, the post-drying treatment has a drying temperature ranging from about 100 to 140 degrees Celsius and drying time of about 50 to 70 seconds. Compared to a drying temperature of less than 100 degrees Celsius, the above drying temperature range can better cure the patterned photoresist film. Compared to a drying temperature greater than 140 degrees Celsius, the above drying temperature range can decrease the probability of generating residues when the photoresist is peeled off subsequently because the photoresist is overly cured. The drying time of about 50 to 70 seconds is used for a similar reason. In particular, the drying temperature for the post-drying treatment may be about 120 degrees Celsius, and the drying time may be about 60 seconds.

At step S8024, the patterned photoresist is used as a mask, and an etching process is performed on the insulating material layer to form a groove on a side of the insulating material layer away from the substrate. The groove can penetrate the entire thickness of the insulating material layer. Alternatively, the depth of the groove may be smaller than the thickness of the insulating material layer.

In this step, the patterned photoresist layer in S8023 may be used as a mask by various methods to etch the insulating material layer, including wet etching and dry etching. Specifically, as shown in FIG. 12, on a side of an insulating material layer 201 away from the substrate 200, etching is performed by using the photoresist 203 in FIG. 11 as a mask, and the residual photoresist is peeled off, thereby forming a groove.

In the above step S803, a first conductive material layer is formed on the insulating material layer in which the groove is formed. As shown in FIG. 13, a first conductive material layer 202 is formed on the insulating material layer 201, wherein the first conductive material layer 202 covers the insulating material layer 201 and fills the groove in the insulating material layer 201.

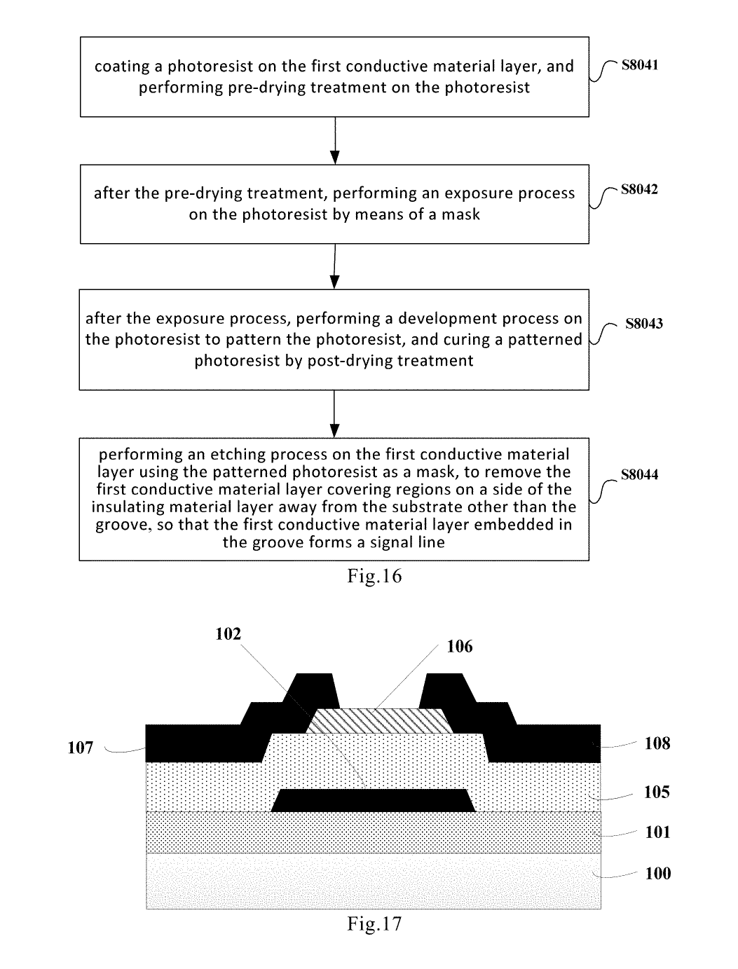

In an exemplary embodiment, in the above step S804, a specific method for performing a patterning process on the first conductive material layer so that the first conductive material layer filled in the groove forms a signal line is as shown in FIG. 16.

Specifically, at step S8041, a photoresist is coated on the first conductive material layer, and the photoresist is subjected to pre-drying treatment.

In the above steps, as shown in FIG. 13, when the first conductive material layer fills the groove in the insulating material layer, a groove is also formed in a region corresponding to the groove in the insulating material layer. Therefore, in the process of coating the photoresist, the photoresist fills the groove in the first conductive material layer, and forms a level difference at the groove boundary of the first conductive material layer, as shown in FIG. 14.

In an exemplary embodiment, the photoresist may have a coating thickness ranging from about 1.1 to 3.1 μm. Compared to a photoresist having a thickness less than 1.1 μm, a photoresist having the above thickness range can decrease the probability of light penetrating the photoresist and causing damage to other layers during photolithography. Compared to a photoresist having at thickness greater than 3.1 μm, a photoresist having the above thickness range makes the film formed by the photoresist more uniform, thereby improving the film formation efficiency of the photoresist.

In an exemplary embodiment, the pre-drying treatment for the photoresist has a drying temperature ranging from about 100 to 110 degrees Celsius and drying time of about 50 to 70 seconds. Compared to a drying temperature of less than 100 degrees Celsius; the above drying temperature range can better cure the photoresist film. Compared to a drying temperature greater than 110 degrees Celsius, the above drying temperature range can decrease the probability of the photoresist remaining on the first conductive material layer after development due to being overly cured. The drying time of about 50 to 70 seconds is used for a similar reason. In particular, the pre-drying time may be specifically about 60 seconds.

At step S8042, after the pre-drying treatment, an exposure process is performed on the photoresist by means of a mask.

It can be understood that when the photoresist used is a positive photoresist, the position and the shape of a light-transmitting region in the mask substantially coincide with the position and the shape of the groove in the first conductive material layer. As will be understood by those skilled in the art, “position and shape substantially coinciding” as used herein includes dimensions that are reserved for the light-transmitting region in the mask in consideration of pattern loss in subsequent photolithographic and etching steps.

At step S8043, after the exposure process, a development process is performed on the photoresist to pattern the photoresist, and a patterned photoresist is cured by post-drying treatment.

In an exemplary embodiment, the post-drying treatment has a drying temperature ranging from about 100 to 140 degrees Celsius and drying time of about 50 to 70 seconds. Compared to a drying temperature of less than 100 degrees Celsius, the above drying temperature range can better cure the patterned photoresist film. Compared to a drying temperature greater than 140 degrees Celsius, the above drying temperature range can decrease the probability of generating residues when the photoresist is peeled off subsequently because the photoresist is overly cured. The drying time of about 50 to 70 seconds is used for a similar reason. In particular, the drying temperature of the post-drying treatment may be about 120 degrees Celsius, and the drying time may be about 60 seconds.

A patterned photoresist is obtained after the development process. As used herein, a patterned photoresist refers to a photoresist that fills the groove on a side of the first conductive material layer away from the substrate. In the case of a positive photoresist, the photoresist in non-groove regions on a side of the first conductive material layer away from the substrate has been removed during development. That is, the position and the shape of the patterned photoresist substantially coincide with the position and the shape of the groove in the first conductive material layer.

At step S8044, an etching process is performed on the first conductive material layer using the patterned photoresist as a mask, so as to remove the first conductive material layer covering regions on a side of the insulating material layer away from the substrate except for the groove, and leave the first conductive material layer filled in the groove as a signal line.

In the step of performing an etching process on the first conductive material layer using the patterned photoresist as a mask, the specific etching method may be consistent with that described above, and details are not described here again.

Since the position and the shape of the patterned photoresist substantially coincide with the position and the shape of the groove in the first conductive material layer (corresponding to the groove in the insulating material layer), the first conductive material layer in the groove on a side of the insulating material layer away from the substrate is reserved during the etching process under the protection of the patterned photoresist, while the first conductive material layer outside the groove in the insulating material layer (outside the coverage area of the patterned photoresist) is removed by etching. After etching, the first conductive material layer (i.e. the patterned first conductive material layer) filled in the groove on a side of the insulating material layer away from the substrate forms a signal line.

FIG. 14 is a schematic view illustrating a process of performing an etching process on the first conductive material layer using the patterned photoresist in the preparation method shown in FIG. 8. As shown in FIG. 14, the width of a mask 206 coincides with the width of the groove in the insulating material layer 201. Therefore, the width of the patterned photoresist 205 also coincides with the width of the groove on the insulating material layer 201. An etching process is performed on the first conductive material layer 202 using the patterned photoresist 205 as a mask. That is, the first conductive material layer 202 in regions not covered by the photoresist is removed. Since the width of the patterned photoresist 205 also coincides with the width of the groove in the insulating material layer 201, removing the first conductive material layer 202 in regions not covered by the photoresist is to remove the first conductive material layer covering regions on a side of the insulating material layer 201 away from the substrate 200 other than the groove, thereby obtaining a patterned first conductive material layer 202 (signal line) as shown in FIG. 15.

In an exemplary embodiment, the thickness of the first conductive material layer is not less than the depth of the groove on a side of the insulating material layer away from the substrate. In particular, in one embodiment, an absolute value of the difference between the thickness of the first conductive material layer and the depth of the groove on a side of the insulating material layer away from the substrate is less than a predetermined threshold. For example, the thickness of the first conductive material layer is slightly greater than the depth of the groove on a side of the insulating material layer away from the substrate. In this way, it is advantageous for reducing the level difference between a plurality of film layers above the signal line on the basis of ensuring the conductivity of the signal line, thereby reducing the probability of breakage of the signal line caused by the level difference between film layers.

In an exemplary embodiment, after performing a patterning process on the first conductive material layer, the above preparation method may further comprise steps of:

forming an insulating layer on the signal line and the insulating material layer;

forming an active layer on the insulating layer and performing a patterning process on the active layer;

forming a second conductive material layer on a patterned active layer, and performing a patterning process on the second conductive material layer to form a source and a drain.

It can be found from FIG. 10 to FIG. 15 that, in the above preparation method for an array substrate provided by an exemplary embodiment, an insulating material layer 201 is formed between the substrate 200 and the first conductive material layer 202, and the insulating material layer can be used as an interface modifying layer, which can solve the problem that poor adhesion between the first conductive material layer 202 and the substrate 200 causes the first conductive material layer 202 to be easily peeled off from the substrate 200.

Further, since the insulating material layer 201 is not electrically conductive, etching is not needed. In practice, when a patterning process is performed on the first conductive material layer 202 using an etching solution, it is difficult for the insulating material layer 201 to be etched by the etching solution. Therefore, exemplary embodiments can avoid the problem that incomplete etching of the barrier metal results in occurrence of an accidental short circuit or other malfunctions in related circuits.

In addition, in exemplary embodiments, when the signal line is being prepared, no barrier metal is introduced, thus the prepared signal line does not contain a barrier metal, so that the metal of the signal line provided by embodiments of the present disclosure is more simplified. In particular, the signal line may include a single metallic material (including reasonable impurities), such as copper. In embodiments of the present disclosure, use of a single metal (e.g. copper) wire with low resistivity can exhibit the advantages of the wire in terms of low resistance, which thus reduces the delay effect of the signal line as well as related elements such as a resistor/capacitor in the array substrate, improves the response speeds of related circuits, and in turn increases the response speed of the entire array substrate.

Moreover, in exemplary embodiments, a groove is formed on a side of the patterned insulating material layer 201 away from the substrate, and the patterned first conductive material layer 202 (signal line) is embedded in the groove, so that a level difference between a plurality of film layers above the signal line resulting from the signal line can be reduced, which in turn decreases the probability of breakage of the signal line caused by the level difference between film layers.

An exemplary embodiment further provides an array substrate. A schematic structural view of the array substrate is shown in FIG. 17, which comprises a substrate 100, an insulating material layer 101, and a signal line 102. As shown in FIG. 17, the insulating material layer 101 is on the substrate 100, and the signal line 102 is on a side of the insulating material layer 101 away from the substrate.

In an exemplary embodiment, the array substrate may further comprise an insulating layer 105, an active layer 106, a source 107, and a drain 108. The insulating layer 105 is on the signal line 102 and the insulating material layer 101, the active layer 106 is on a side of the insulating layer 105 away from the signal line 102, and the source 107 and the drain 108 are on a side of the insulating layer 105 and the active layer 106 away from the signal line 102 or the insulating material layer 101.

In an exemplary embodiment, the material of the insulating material layer 101 may include one or more of silicon nitride, silicon oxide, titanium oxide and aluminum oxide, and the material of the signal line 102 may include copper.

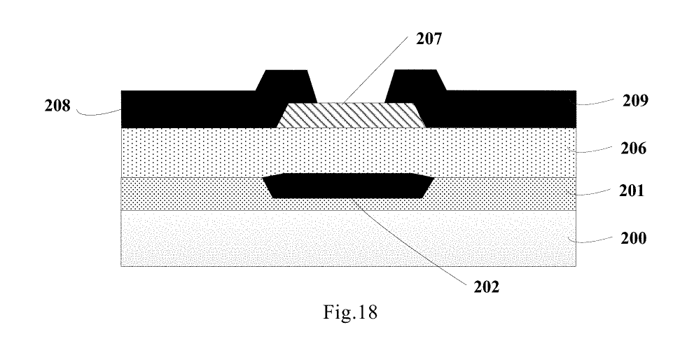

An exemplary embodiment further provides another array substrate, as shown in FIG. 18, which comprises a substrate 200, an insulating material layer 201, and a signal line 202. As shown in FIG. 18, the insulating material layer 201 is on the substrate 200, the signal line 202 is on a side of the insulating material layer 201 away from the substrate 200, a groove is disposed on a side of the insulating material layer 201 away from the substrate 200, and the signal line 202 is embedded in the groove.

In an exemplary embodiment, the array substrate may further comprise an insulating layer 206, an active layer 207, a source 208, and a drain 209. As shown in FIG. 18, the insulating layer 206 is on the signal line 202 and the insulating material layer 201, the active layer 207 is on a side of the insulating layer 206 away from the signal line 202, and the source 208 and the drain 209 are on a side of the insulating layer 206 and the active layer 207 away from the signal line 202 or the insulating material layer 201.

In an exemplary embodiment, the material of the insulating material layer 201 may include silicon nitride, silicon oxide, titanium oxide, or aluminum oxide, and the material of the signal line 202 may include copper.

The structures of the array substrate provided above are only illustrative. Those skilled in the art can devise array substrates having other structures under the teaching of the present disclosure. No particular limitation is imposed in this regard in the present disclosure.

A further exemplary embodiment provides a display device comprising any of the array substrates described above.

Those skilled in the art may understand that steps, measures and schemes in the various operations, methods and flows that have been discussed in the present disclosure may be substituted, modified, combined or deleted. Further, other steps, measures and schemes having the various operations, methods and flows that have been discussed in the present disclosure may also be substituted, modified, rearranged, decomposed, combined or deleted. Further, steps, measures and schemes in the prior art having the various operations, methods and flows that have been disclosed in the present disclosure may also be substituted, modified, rearranged, decomposed, combined or deleted.

What have been stated above are only part of the embodiments of the present disclosure. It is to be noted that a number of improvements and modifications may be further made by those ordinarily skilled in the art without departing from the principle of the present disclosure. These improvements and modifications shall also be regarded as falling within the scope of the present disclosure.

1. A method for preparing an array substrate, comprising:
forming an insulating material layer on a substrate;
forming a first conductive material layer on the insulating material layer; and
performing a patterning process on the first conductive material layer to form a plurality of signal lines arranged in an array.

2. The method according to claim 1, wherein after forming an insulating material layer on the substrate, the method further comprises:
performing a patterning process on the insulating material layer to form a groove on a side of the insulating material layer away from the substrate.

3. The method according to claim 2, wherein said forming a first conductive material layer on the insulating material layer and performing a patterning process on the first conductive material layer to form a plurality of signal lines arranged in an array, include:
forming a first conductive material layer on a patterned insulating material layer, so that the first conductive material layer covers and fills the groove;
performing a patterning process on the first conductive material layer to remove the first conductive material layer covering regions on a side of the insulating material layer away from the substrate other than the groove, so that the first conductive material layer filling the groove forms the signal lines.

4. The method according to claim 2, wherein a depth of the groove is not greater than a thickness of the insulating material layer.

5. The method according to claim 2, wherein said performing a patterning process on the insulating material layer includes:
coating a photoresist on the insulating material layer, and performing pre-drying treatment on the photoresist;
after the pre-drying treatment, performing an exposure process on the photoresist by means of a mask;
after the exposure process, performing a development process on the photoresist to pattern the photoresist, and curing a patterned photoresist by post-drying treatment; and
performing an etching process on the insulating material layer using the patterned photoresist as a mask to form a groove on a side of the insulating material layer away from the substrate.

6. The method according to claim 5, wherein the photoresist has a coating thickness ranging from about 1.1 to 3.1 μm.

7. The method according to claim 5, wherein the pre-drying treatment has a drying temperature ranging from about 100 to 110 degrees Celsius and drying time of about 50 to 70 seconds.

8. The method according to claim 5, wherein the photoresist after the pre-drying treatment has a thickness ranging from about 1.0 to 3.0 μm.

9. The method according to claim 5, wherein the post-drying treatment has a drying temperature ranging from about 100 to 140 degrees Celsius and drying time of about 50 to 70 seconds.

10. The method according to claim 1, wherein after performing a patterning process on the first conductive material layer, the method further comprises:
forming an insulating layer on the signal line and the insulating material layer;
forming an active layer on the insulating layer, and performing a patterning process on the active layer; and
forming a second conductive material layer on an patterned active layer and the insulating layer, and performing a patterning process on the second conductive material layer to form a source and a drain.

11. The method according to claim 1, wherein a material of the insulating material layer includes one or more of silicon nitride, silicon oxide, titanium oxide and aluminum oxide, and the first conductive material layer includes copper.

12. The method according to claim 11, wherein the thickness of the insulating material layer ranges from about 100 to 400 nanometers.

13. An array substrate comprising a substrate, an insulating material layer, and a signal line, wherein
the insulating material layer is on the substrate;
the signal line is on a side of the insulating material layer away from the substrate.

14. The array substrate according to claim 13, wherein a groove is disposed on a side of the insulating material layer away from the substrate, and the signal line is embedded in the groove.

15. The array substrate according to claim 13, further comprising an insulating layer, an active layer, a source and a drain, wherein
the insulating layer is on the signal line and the insulating material layer;
the active layer is on a side of the insulating layer away from the signal line;
the source and the drain are on sides of the insulating layer and the active layer away from one of the signal line and the insulating material layer.

16. A display device comprising the array substrate according to claim 13.

17. The display device according to claim 16, wherein a groove is disposed on a side of the insulating material layer away from the substrate, and the signal line is embedded in the groove.

18. The display device according to claim 16, further comprising an insulating layer, an active layer, a source and a drain, wherein
the insulating layer is on the signal line and the insulating material layer;
the active layer is on a side of the insulating layer away from the signal line;
the source and the drain are on sides of the insulating layer and the active layer away from one of the signal line and the insulating material layer.

19. The method according to claim 2, wherein a material of the insulating material layer includes one or more of silicon nitride, silicon oxide, titanium oxide and aluminum oxide, and the first conductive material layer includes copper.

20. The method according to claim 3, wherein a material of the insulating material layer includes one or more of silicon nitride, silicon oxide, titanium oxide and aluminum oxide, and the first conductive material layer includes copper.
